(19) United States
(12) Patent Application Publication
(10) Pub. No.: US 2024/0213106 A1
(43) Pub. Date: Jun. 27, 2024

(54) SEMICONDUCTOR DEVICE

(71) Applicants: DYNEX SEMICONDUCTOR LIMITED, Lincoln (GB); ZHUZHOU CRRC TIMES SEMICONDUCTOR CO. LTD, Zhuzhou (CN)

(72) Inventors: Robin Adam SIMPSON, Lincoln (GB); Michael David NICHOLSON, Lincoln (GB); Yangang WANG, Lincoln (GB)

(21) Appl. No.: 17/928,809

(22) PCT Filed: Jul. 19, 2021
(86) PCT No.: PCT/EP2021/070115

§ 371 Date: Nov. 30, 2022

(51) Int. Cl. H01L 23/051; H01L 23/00; H01L 25/07

(52) U.S. Cl. CPC H01L 23/051; H01L 24/72; H01L 24/90; H01L 25/072; H01L 2224/72; H01L 2224/90; H01L 2924/10253; H01L 2924/10271; H01L 2924/10272; H01L 2924/1033; H01L 2924/1203; H01L 2924/1302; H01L 2924/13023; H01L 2924/1305; H01L 2924/13055; H01L 2924/13091

(57) ABSTRACT

There is provided a semiconductor device 1 which comprises: a housing comprising a first housing electrode 5 and a second housing electrode 4 which are arranged at opposite sides of the housing; a plurality of semiconductor units 30 arranged within the housing between the first and second housing electrodes 4, 5; a plurality of pressure means 40 for applying pressure to the plurality of semiconductor units 30, respectively, wherein the plurality of pressure means 40 are arranged between the plurality of semiconductor units 30 and the first housing electrode 5; a first conductive structure 14 arranged between the plurality of pressure means 40 and the plurality of semiconductor units 30, wherein the plurality of semiconductor units 30 are electrically connected in parallel between the second housing electrode 4 and the first conductive structure 14; and a second conductive structure 18 configured to provide a current flow path from the first conductive structure 14 to the first housing electrode 5, the second conductive structure comprising a first part 16 that is fixedly connected to the first conductive structure 14 and a second part 9 that is fixedly connected to the first housing electrode 5.

### TECHNICAL FIELD

The present disclosure relates to a semiconductor device. More particularly, but not exclusively, the present disclosure relates to a pressure-contact power semiconductor device, which uses pressure means (e.g., springs) to mitigate the contact pressure imbalance across all chips within the device and also provides an improved current bypass mechanism which routes electrical currents around the pressure means.

### BACKGROUND

A power semiconductor device may house one or more power semiconductor chips (or dies). The power semiconductor chips are often used to switch high currents and voltages, and may include one or more of a power transistor, a power diode, and a thyristor, etc. A power transistor includes, but is not limited to, a power metal-oxide-semiconductor field effect transistor (MOSFET), a power bipolar junction transistor (BJT), and an insulated gate bipolar transistor (IGBT), etc. A thyristor includes, but is not limited to, an integrated gate-commutated thyristor (IGCT), and a gate turn-off thyristor (GTO), etc. The power semiconductor device may also be referred to as a power module or a power electronic module.

FIG. 1 schematically illustrates a sectional view of a known power semiconductor device 100 which has a press-pack package. Press-pack power semiconductor devices are an alternative to traditional isolated-base power semiconductor devices, in which power semiconductor chips are typically soldered on isolated substrates that carry the chips respectively and are also wire-bonded to the substrates. Instead of the wire bonds and solder joints used in isolated-base devices, press-pack devices typically rely on the application of force by an external clamping system, to make contact to the chips. In this sense, the power semiconductor device 100 may also be referred to as a pressure-contact power semiconductor device.

As shown in FIG. 1, the press-pack power semiconductor device 100 comprises a plurality of semiconductor chips 120. Individual semiconductor chips 120 are connected in parallel within a single pressure contact housing to produce a single device containing multiple chips with a current handling capability that is ideally the sum of the capability of all the chips contained within the housing. The semiconductor chips 120 are placed between mechanical strain buffers 102, 103 to form semiconductor units 130. These semiconductor units 130 are then positioned between upper and lower electrodes 104, 105 in a hermetically-sealed housing which is formed by the electrodes 104, 105, a ceramic tube 108 and thin flanges 106, 107, 109. The thin flanges include a lid flange 106, a housing upper flange 107, and a housing lower flange 109. The thin flanges 106, 107, 109 make a gas-tight, flexible joint between the electrodes 104, 105 and the ceramic tube 108. The upper and lower electrodes 104, 105 may also be referred to as housing electrodes. The hermetically-sealed housing encloses an internal space 111. The internal space 111 is commonly filled with nitrogen.

It is typical that one electrode (e.g., the upper electrode 104) is flat and the other (e.g., the lower electrode 105) has an array of pillars 110 formed on its inner surface. The semiconductor units 130 typically have upper and lower contact regions of differing areas. As shown in FIG. 1, the pillars 110 of the lower electrode 105 permit contact to the smaller areas at the bottom surfaces of the chips 120.

In operation, the semiconductor chips 120 are electrically and thermally connected between the upper and lower electrodes 104, 105 by pressure. One or both of the interface between the semiconductor units 130 and the upper electrode 104, and the interface between the semiconductor units 130 and the lower electrode 105 are dry interfaces. A dry interface means that elements at opposite sides of the interface are coupled by pressure, and there is no bonding material between the elements.

For optimum current handling capability and product reliability, the contact pressures between the chips 120 and the housing electrode(s) 104, 105 should be as uniform as possible, and the contact pressure between each chip and the housing electrode(s) 104, 105 should be within a defined operating range. This is however difficult to achieve, as micron-level differences in the thicknesses of the semiconductor units 130 and/or surface flatness variations across the housing electrodes 104, 105 can lead to applied pressures that differ greatly between the chips 120 and also differ from the intended target pressure. Further, the flatness of assembly components, such as heatsinks, used in the end-users' applications and whether such components are parallel to the housing electrode(s) 104, 105 would also have significant effects on the pressure non-uniformity across the chips 120. In addition, self-heating effects in the device 100 may result in thermal warpage of the electrodes 104, 105, causing further pressure imbalance across the chips 120. The pressure imbalance across the chips 120 in turn leads to differences in electrical and thermal contact resistances between the chips 120 and the housing electrodes 104, 105. It is known that the performance of the chips 120 is affected by the level of applied pressure in pressure-contact applications, such that under- or over-pressurisation can result in sub-optimal performance and poor reliability.

There are two existing solutions to this problem. The first solution is to use extremely tightly toleranced components (typically matched to within a few micrometres), to ensure component thicknesses are as closely matched as possible. Tight component tolerance ranges become hard to manage with large numbers of components, as is the case in large-area multi-chip pressure contact devices (e.g., the device 100).

The second solution is to use individual disc spring stacks 140 in line with each individual chip within the housing in order to reduce the force/displacement ratio. In this way, for a given difference in component stack thickness or a given flatness variation, the difference in contact pressure is minimised. However, the disc spring stacks 140 are relatively poor electrical conductors. Thus, a current bypass mechanism has to be provided to route the majority (if not all) of the electrical currents into/from the chips 120 around the disc spring stacks 140.

Two approaches are known for the design of the current bypass mechanism. The first approach, described in EP1393373A1, uses small metallic strips 118 that connect to the top and bottom of the disc spring stacks 140 by pressure. This design is schematically shown in FIG. 3. In this approach individual current bypass is provided for each disc spring stack 140. The cross-sectional area of each bypass metallic strip 118 is sufficient to carry the operating current of a single semiconductor chip 120 during normal operation, but in a type of failure mode, known as the short-circuit failure mode, one chip 120 and therefore one metallic strip 118 may be required to carry the operating current of the entire device 100. As the device 100 contains multiple chips 120, the current flowing through the one metallic strip 118 would increase by a factor identical to the number of chips 120 during the short-circuit failure mode of the device 100. This may exceed the conducting capability of the one metallic strip 118 and cause it to melt.

The second approach is described in WO2017/220949A1 (with particular reference to FIGS. 10 and 11 of WO2017/220949A1). This approach uses a combination of a conductive diaphragm 14 and a spring locator 10 to form a current bypass mechanism around the disc spring stacks 12. For the second approach, the current bypass around the disc spring stacks 12 is common to all of the chips/spring stacks, so the current density in the bypass is not significantly affected in the event of operation in the short-circuit failure mode. This approach is, however, dependent on a number of pressure contacts being made. The pressure contacts are vulnerable to under-pressurisation and fretting wear. The fretting wear may occur during the normal power cycling of the device. Therefore, the current bypass mechanism provided by the second approach may degrade through the product lifetime.

It is an object of the present disclosure, among others, to provide an improved semiconductor device, which solves problems associated with known semiconductor devices, whether identified herein or otherwise.

### SUMMARY

According to a first aspect of the present disclosure, there is provided a semiconductor device, comprising:
a housing comprising a first housing electrode and a second housing electrode which are arranged at opposite sides of the housing;
a plurality of semiconductor units arranged within the housing between the first and second housing electrodes;
a plurality of pressure means for applying pressure to the plurality of semiconductor units, wherein the plurality of pressure means are arranged between the plurality of semiconductor units and the first housing electrode;
a first conductive structure arranged between the plurality of pressure means and the plurality of semiconductor units, wherein the plurality of semiconductor units are electrically connected in parallel between the second housing electrode and the first conductive structure; and
a second conductive structure configured to provide a current flow path from the first conductive structure to the first housing electrode, the second conductive structure comprising a first part that is fixedly connected to the first conductive structure and a second part that is fixedly connected to the first housing electrode.

The second conductive structure functions as a current bypass mechanism which routes electrical currents (to/from the plurality of semiconductor units) around the pressure means without passing through the pressure means. By arranging the plurality of semiconductor units to be electrically connected in parallel between the second housing electrode and the first conductive structure, and by configuring the second conductive structure to provide a current flow path from the first conductive structure to the first housing electrode, the current flow path is shared by all of the plurality of semiconductor units, and thus is able to reliably carry the operating current of the entire semiconductor device. In this way, the current density in the second conductive structure would not be significantly affected in the event of operation in the short-circuit failure mode. Accordingly, the second conductive structure can reliability conduct current during the short-circuit failure mode.

Further, by configuring the second conductive structure such that a first part thereof is fixedly connected to the first conductive structure and a second part thereof is fixedly connected to the first housing electrode, the current flow path from the first conductive structure to the first housing electrode does not rely upon pressure contacts between the second conductive structure, on the one hand, and the first conductive structure or the first housing electrode, on the other hand. Therefore, the current flow path is robust and reliable, and would not degrade noticeably throughout the lifetime of the semiconductor device.

The first conductive structure may be an electrically and thermally conductive structure. Further or alternatively, the second conductive structure may be an electrically and thermally conductive structure.

Since the first conductive structure is arranged between the plurality of pressure means and the plurality of semiconductor units, it would be understood that the plurality of pressure means apply pressure to the plurality of semiconductor units via the first conductive structure.

The term “fixedly connected” used in the present disclosure means that the connected elements may be integrally formed or, alternatively, may be securedly bonded together (e.g., by a soldering, sintering or brazing process) such that the fixedly connected elements can be handled as a single-piece item. It would be appreciated that elements which form pressure contact with one another are not fixedly connected.

The first part may be fixedly connected to the second part.

The plurality of semiconductor units may be electrically and thermally coupled to each of the first and second housing electrodes. It would be understood that the plurality of semiconductor units comprise at least two semiconductor units.

At least one of the second housing electrode and the first conductive structure may form a pressure contact with the semiconductor units.

The plurality of semiconductor units may be electrically and thermally coupled to one another via the first conductive structure.

The first conductive structure may be a unitary one-piece structure. In other words, component(s) of the first conductive structure may be integrally formed with one another.

The first conductive structure may comprise a base plate and a plurality of pillars. The base plate may comprise a first surface facing the plurality of semiconductor units and a second surface opposite to the first surface. The plurality of pillars may extend from the first surface of the base plate, and may be electrically coupled to the plurality of semiconductor units, respectively.

At least one of the plurality of pillars may extend along a first direction between the first and second housing electrodes. The base plate may extend along a first plane which is perpendicular to the first direction.

The first/second housing electrode may extend along a second plane, which is parallel to the first plane.

The semiconductor device may further comprise a circuit board which is supported by the base plate (in particular, the first surface of the base plate).

The semiconductor device may further comprise electrical connectors which electrically connect the plurality of semiconductor units to the circuit board. The electrical connectors may comprise spring loaded pins.

At least one of the plurality of pressure means may be elastic.

The plurality of pressure means may be configured to apply pressure to the plurality of semiconductor units when the plurality of pressure means are compressed between the first housing electrode and the first conductive structure.

At least one of the plurality of pressure means may comprise a spring. More specifically, at least one of the plurality of pressure means may comprise a disc spring stack.

The semiconductor device may further comprise a plurality of holders for keeping the plurality of pressure means in place within the housing.

The plurality of holders may be attached to an inner surface of the first housing electrode. The holders may comprise spring locator posts.

The first conductive structure may comprise a plurality of recesses for engaging with the plurality of holders, respectively.

The plurality of pressure means may be configured to apply pressure to the plurality of semiconductor units when the plurality of recesses engage with the plurality of holders, respectively.

The pressure means may be configured to apply maximum pressure to the plurality of semiconductor units when the first housing electrode is pressed flat by an external clamping system.

The housing may further comprise a tubular housing element arranged between the first and second housing electrodes and surrounding the plurality of semiconductor units. The tubular housing element may be configured to electrically isolate the first and second housing electrodes from one another.

The tubular housing element may be configured such that, once the first housing electrode is pressed flat by the external clamping system, further mechanical loading provided by the external clamping system is applied to the tubular housing element.

The second conductive structure may comprise a tubular conductive structure arranged within the housing.

The tubular conductive structure may surround the plurality of pressure means.

The tubular conductive structure may be arranged between the plurality of pressure means and the tubular housing element.

The tubular conductive structure may comprise a wall, and a thickness of the wall is between 0.1 mm and 0.5 mm.

It would be appreciated that the range of the wall thickness may allow for a degree of variability, for example, +20%, in the stated values of the end points of the ranges.

At least a part of the wall of the tubular conductive structure may have a curved contour along a direction parallel to a central axis of the tubular conductive structure.

The tubular conductive structure may be formed integrally with the first conductive structure.

The tubular conductive structure may comprise a first end facing the second housing electrode and a second end opposite to the first end. The first and second ends of the tubular conductive structure may be the first and second parts of the second conductive structure, respectively.

The housing may further comprise a first flange connecting the first housing electrode to the tubular housing element, and a second flange connecting the second housing electrode to the tubular housing element.

The second conductive structure may further comprise the first flange. The first flange may be fixedly connected to the tubular conductive structure. The tubular conductive structure may comprise the first part, and the first flange may comprise the second part.

The tubular conductive structure may be attached to an inner surface of the tubular housing element.

At least one of the semiconductor units may comprise a semiconductor chip.

At least one of the semiconductor units may further comprise first and second strain buffers arranged at opposite surfaces of the respective semiconductor chip.

The semiconductor device may be a power semiconductor device. At least one of the plurality of semiconductor units may be a power semiconductor unit comprising a power semiconductor chip.

According to a second aspect of the present disclosure, there is provided a method of manufacturing a semiconductor device, comprising:
providing a housing, wherein the housing comprises a first housing electrode and a second housing electrode which are arranged at opposite sides of the housing, arranging a plurality of semiconductor units within the housing between the first and second housing electrodes;
providing a plurality of pressure means for applying pressure to the plurality of semiconductor units, wherein the plurality of pressure means are arranged between the plurality of semiconductor units and the first housing electrode;
arranging a first conductive structure between the plurality of pressure means and the plurality of semiconductor units, wherein the plurality of semiconductor units are electrically connected in parallel between the second housing electrode and the first conductive structure; and
providing a second conductive structure for providing a current flow path from the first conductive structure to the first housing electrode, the second conductive structure comprising a first part that is fixedly connected to the first conductive structure and a second part that is fixedly connected to the first housing electrode.

The first part may be integrally formed with the first conductive structure.

Alternatively, the first part may be securedly attached to the first conductive structure, by a bonding process (e.g., brazing, soldering, or welding etc.).

The second part that may be securedly attached to the first housing electrode by a bonding process (e.g., brazing, soldering, or welding etc.).

Where appropriate any of the optional features described above in relation to the first aspect of the present disclosure may be applied to the second aspect of the disclosure.

The expression “integrally formed” used in the present disclosure means that integrally formed elements are connected together so as to make up a single complete piece or unit, and so as to be incapable of being easily dismantled without destroying the integrity of the piece or unit.

The term “about” or “approximately” used in the present disclosure indicates a degree of variability (e.g., 20%) in the stated numerical values.

The terms “electrically coupled” and “thermally coupled” used in the present disclosure means that one or more intervening elements may be connected between the coupled elements.

It would also be understood that the terms “first”, “second” and “third” are simply used in the present disclosure to label the relevant elements (“conductive structure”, “housing electrodes”, “direction”, “plane” etc.) for the ease of description, and do not imply any limitations to the sequence or locations of the relevant elements.

### BRIEF DESCRIPTION OF THE DRAWINGS

In order that the disclosure may be more fully understood, a number of embodiments of the disclosure will now be described, by way of example, with reference to the accompanying drawings, in which:

FIG. 1 schematically illustrates a sectional view of a prior semiconductor device;

FIG. 2 schematically illustrates a sectional view of another prior semiconductor device;

FIG. 3 schematically illustrates a sectional view of a further prior semiconductor device;

FIG. 4 schematically illustrates a sectional view of a semiconductor device according to a first embodiment of the present disclosure when the semiconductor device is not mechanically loaded;

FIG. 5 schematically illustrates conductive paths through the semiconductor device of FIG. 4 and mechanical load transmissions across the semiconductor device when the semiconductor device is mechanically loaded;

FIG. 6 schematically illustrates a sectional view of a semiconductor device according to a second embodiment of the present disclosure;

FIG. 7 schematically illustrates a sectional view of a semiconductor device according to a third embodiment of the present disclosure;

FIG. 8 shows process steps of a method for manufacturing a semiconductor device.

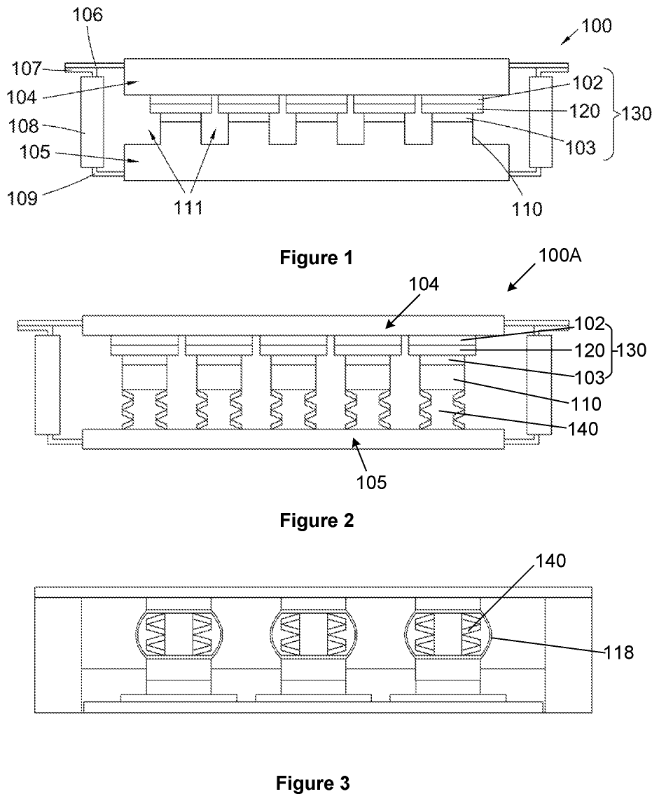

In the figures, like parts are denoted by like reference numerals.

It will be appreciated that the drawings are for illustration purposes only and are not drawn to scale.

### DETAILED DESCRIPTION OF THE PREFERRED EMBODIMENTS

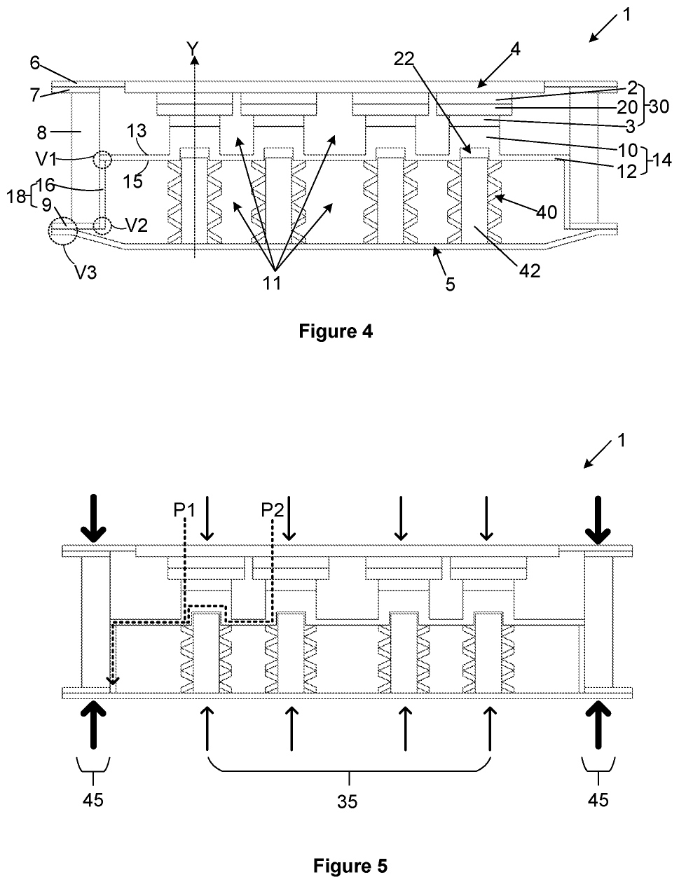

FIGS. 4 and 5 schematically illustrates cross sectional views of a semiconductor device 1 (referred to as the “device” below) according to a first embodiment of the present disclosure. In this embodiment, the semiconductor device 1 is embodied as a multi-chip press-pack power semiconductor device. In FIG. 4, the device 1 is not mechanically loaded by any external clamping system. In FIG. 5, the device 1 is mechanically loaded across its full width by an external clamping system.

As shown in FIG. 4, the device 1 comprises an upper electrode 4 and a lower electrode 5 arranged at opposite sides of the device 1. The upper electrode 4 and the lower electrode 5 may also be referred to as housing electrodes. The lower electrode 5 may be referred to as a “first housing electrode”, and the upper electrode 4 may be referred to as a “second housing electrode”. Each of the upper electrode 4 and the lower electrode 5 takes the form of an electrode plate which has generally flat inner and outer surfaces, with the inner surface facing the semiconductor units 30 and the outer surface exposed to an exterior of the device 1. However, when the device 1 is not mechanically loaded (as shown in FIG. 4), a plurality of pressure means 40 tend to push the lower electrode 5 outwards to make the lower electrode 5 slightly bulge. The plurality of pressure means 40 are described below in more detail.

The device 1 further comprises upper strain buffers 2, lower strain buffers 3, and a plurality of power semiconductor chips 20 (referred to as the “chips” below). The upper strain buffers 2 and the lower strain buffers 3 are arranged at opposite surfaces of the chips 20. The upper and lower electrodes 4, 5 are typically made of copper. The upper strain buffers 3 and the lower strain buffers 4 are typically made of molybdenum. The power semiconductor chips 20 may be made in silicon technology, or alternatively may be based upon other types of semiconductors, such as, silicon carbide, gallium nitride, or silicon germanium etc. The chips 20 may comprise one or more of a power transistor (e.g., an IGBT, a power MOSFET, a power BJT), a power diode, and a power thyristor (e.g., an IGCT, a GTO) etc.

During normal operation of the device 1, the device 1 heats and cools, and consequently each component of the device 1 undergoes thermal expansion and contraction. Difference in the thermal expansion coefficients of adjacent components leads to abrasive wear (also called “fretting”) of their contact surfaces. The thermal expansion coefficients of silicon and molybdenum are more closely matched than those of silicon and copper. The strain buffers 2, 3 are useful for reducing the rate of wear on the surfaces of the chips 20. The chips 20 may be silver sintered (or otherwise bonded) to the strain buffers 2, 3 to further reduce the risks of fretting and reduce the thermal resistance of the chips 20. A combination of a single chip 20 with its associated strain buffers 2, 3 may be referred to as a semiconductor unit 30. It would, however, be appreciated that the strain buffers 2, 3 may be wholly or partly omitted from the semiconductor units 30. As shown by FIG. 4, the semiconductor units 30 are laterally spaced to one another. The semiconductor units 30 are electrically connected in parallel between the upper electrode 4 and the lower electrode 5. Therefore, the overall current rating of the device 1 is generally determined by the number of semiconductor units 30 paralleled inside the device 1 and the current rating of each semiconductor unit 30.

The device 1 further includes a lid flange 6, a housing upper flange 7, a tubular housing element 8, and a housing lower flange 9. These components form a gas-tight (or hermetic) connection between the upper electrode 4 and the lower electrode 5. The tubular housing element 8 is of a tubular shape and surrounds the semiconductor units 30. A cross section of the tubular housing element 8 is typically square or circular but may take any suitable shape. Further, the tubular housing element 8 extends between the upper and lower electrodes 4, 5. The housing lower flange 9 connects the lower electrode 5 with the tubular housing element 8, and may be referred to as a “first flange”. The lid flange 6 and the housing upper flange 7 connect the upper electrode 4 with the tubular housing element 8, and may be collectively referred to as a “second flange”. Each of the flanges 6, 7, 9 is loop shaped and generally follows the shape of the tubular housing element 8. As shown in FIG. 4, the housing lower flange 9 is fixedly bonded to the lower electrode 5 at an interface V3 therebetween. The interface V3 is between a radially outer end of the housing lower flange 9 and a radially outer end of the lower electrode 5.

The electrodes 4, 5, the flanges 6, 7, 9 as well as the tubular housing element 8 together form a hermetic housing of the device 1. The semiconductor units 30 are located within the housing between the upper and lower electrodes 4, 5. The housing encloses an internal space 11 which is typically filled with an inert gas (e.g., nitrogen) at a suitable pressure (e.g., approximately one standard atmospheric pressure) to ensure reliable operation of the chips 20. While FIG. 4 shows that the internal space 11 includes separate sections located at opposite sides of each semiconductor unit 30, it would be understood that the separate sections are in fact interconnected in the third dimension relative to the cross-sectional plane of FIG. 4.

The tubular housing element 8 comprises an electrically insulating material (e.g., ceramic) and electrically isolates the upper electrode 4 from the lower electrode 5. It would be appreciated that the tubular housing element 8 may comprise electrically conductive material(s) (e.g., a tubular conductive structure 16B of FIG. 7) as far as the electrically conductive material(s) do not form a conducting path between the housing electrodes 4, 5. The flanges 6, 7, and 9 may be made of copper or nickel-iron.

Apart from the semiconductor units 30, the hermetic housing of the device 1 further encloses a first conductive structure 14, a tubular conductive structure 16, a plurality of pressure means 40 and a plurality of holders 42. These structures are described below in more detail.

As shown in FIG. 4, the first conductive structure 14 is located between the semiconductor units 30 and the plurality of pressure means 40. The first conductive structure 14 comprises a base plate 12, and a plurality of pillars 10 which are integrally formed with the base plate 12. The base plate 12 is generally of a disc shape, and comprises a first surface 13 facing the semiconductor units 30 and a second surface 15 which is opposite to the first surface 13. The plurality of pillars 10 extend between the first surface 13 and respective ones of the semiconductor units 30. With reference to FIG. 4, the pillars 10 are laterally spaced and parallel to one another, and each of the pillars 10 extends along a vertical Y direction (also referred to as the “first direction”) which is generally perpendicular to the surfaces of the housing electrodes 4, 5. The base plate 12 extends along a plane (not labelled in FIG. 4) which is perpendicular to the vertical Y direction. In the example of FIG. 4, the base plate 12 extends to the inner surface of the tubular housing element 8. Therefore when viewed along the Y direction, the shape of the base plate 12 follows the shape of the tubular housing element 8 (which is typically circular or square as described above).

A plurality of recesses 22 are formed at the second surface 15 of the base plate 12. The recesses 22 are sized to engage with the plurality of holders 42 as described below in more detail.

The first conductive structure 14 is made of an electrically and thermally conductive material (e.g., annealed copper). The first conductive structure 14 may be formed by applying a milling process to opposite surfaces of a block of annealed copper. The pillars 10 are electrically and thermally coupled to respective ones of the semiconductor units 30. The semiconductor units 30 have upper and lower contact regions of differing areas. The pillars 10 permit contact to the smaller areas at the bottom surfaces of the semiconductor units 30. The base plate 12 extends between the pillars 10 and electrically and thermally couples the pillars 10 to one another. Therefore, the semiconductor units 30 are electrically connected in parallel between the upper electrode 4 and the first conductive structure 14.

In addition, it has been found that differences in chip temperatures within the device 1 limit the performance and reliability of the device 1. By thermally coupling the pillars 10 to one another, the base plate 12 is useful for reducing the temperature differences between the chips 20, and thus improves the performance of the device 1. While FIG. 4 shows that the base plate 12 extends continuously between the pillars 10, it would be understood that the base plate 12 may comprise holes, and the holes may be useful for making connections between opposite sides of the base plate 12.

The plurality of pressure means 40 are located between the first conductive structure 14 and the lower electrode 5, and are used for applying pressure to the semiconductor units 30 via the first conducting structure 14. In general, the pressure means 40 are elastic objects, meaning that the pressure means 40 are able to resist a distorting influence and to return to the original configuration when that influence is removed. More specifically, the pressure means 40 get compressed when a compression load is applied across the pressure means 40, and the compression of the pressure means 40 in turn applies pressure to the semiconductor units 30.

The pressure means 40 may comprise a spring, in particular, a compression spring. In the example of FIGS. 4 and 5, each of the pressure means 40 is embodied as a disc spring stack. A disc spring (also referred to as a Belleville washer or a Belleville spring) is a type of spring which resembles a conical shell and can be loaded along its axis either statically or dynamically. A disc spring stack is formed by stacking multiple disc springs together, in the same orientation (i.e., in parallel) or in an alternating orientation (i.e., in series), depending upon the desired spring constant and the desired amount of deflection.

It would be appreciated that the plurality of pressure means 40 may take any suitable form which allow them to apply pressure to the semiconductor units 30. For example, the pressure means 40 may comprise a different type of compression spring (e.g., helical/coil springs, machined springs, etc.). Alternatively, the pressure means 40 may comprise elastic objects (e.g., compressible blocks) which are non-springs.

The plurality of holders 42 keep the pressure means 40 in place within the housing of the device 1, and are located between the first conductive structure 14 and the lower electrode 5. The plurality of holders 42 may be operatively coupled to the lower electrode 5. In the examples of FIGS. 4 and 5, the holders 12 are spring location posts, which are attached to an inner surface of the lower electrode 5 and extend through the central holes of the disc spring stacks. It would of course be understood that the holders 12 may take a different form depending upon the design of the pressure means 40.

The tubular conductive structure 16 is made of an electrically and thermally conductive material, such as, copper or nickel-iron. It surrounds the plurality of pressure means 40 and is located between the pressure means 40 and the tubular housing element 8. FIG. 4 shows that the tubular conductive structure 16 is located in close proximity to the inner surface of the tubular housing element 8. It would be understood that this arrangement is not necessary and that the tubular conductive structure 16 may be spaced apart from the tubular housing element 8 suitably. The shape of the tubular conductive structure 16, when viewed along the Y direction, may follow the shape of the tubular housing element 8 (which is typically circular or square). Again, it would be appreciated that this is not necessary and that the tubular conductive structure 16 may have any suitable shape when viewed along the Y direction.

The tubular conductive structure 16 has an upper end which is fixedly connected to a radially outer end of the base plate 12, forming an interface V1 therebetween. The tubular conductive structure 16 also has a lower end which is fixedly connected to a radially inner end of the housing lower flange 9, forming an interface V2 therebetween. Elements across the interface V1 or V2 are securedly bonded together, by for example a soldering, sintering or brazing process. As described above, the housing lower flange 9 is also securedly bonded to the lower electrode 5, forming an interface V3 therebetween. Therefore, a fully bonded electrical conducting path (or current flow path) is provided from the first conductive structure 14 to the lower electrode 5, via the tubular conductive structure 16 and the housing lower flange 9. Because elements forming the electrical conducting path are fixedly connected to one another, the electrical conducting path is not reliant on any pressure contact.

The tubular conductive structure 16 and the housing lower flange 9 may be collectively referred to as a “second conductive structure” 18 that provides a current flow path from the first conductive structure 14 to the lower electrode 5. The second conductive structure 18 has a first part (e.g., the tubular conductive structure 16) that is fixedly connected to the first conductive structure 14, and a second part (e.g., the housing lower flange 9) that is fixedly connected to the lower electrode 5.

In operation, the device 1 is mechanically loaded across its full width by an external clamping system. This cause the top ends of the holders 12 to move towards and into the recesses 22 of the base plate 12, and in turn causes the plurality of pressure means 40 to be compressed between the base plate 12 and the lower electrode 5, until the lower electrode 5 is pressed flat as shown in FIG. 5. The compressed pressure means 40, due to their elastic nature, apply pressure to the semiconductor units 30 via the first conductive structure 14.

By applying pressure to the semiconductor units 30, at least one of the upper electrode 4 and the first conductive structure 14 forms a pressure contact with the semiconductor units 30. The remaining one (if any) of the upper electrode 4 and the first conductive structure 14 would be fixedly bonded to the semiconductor units 30, by for example using a bonding material. “Pressure contact” means that a dry interface is formed between the semiconductor units 30 and at least one of the upper electrode 4 and the first conductive structure 14. A dry interface means that elements at opposite sides of the interface are coupled by pressure, and there is no bonding material between the elements. Thus, when the device 1 is mechanically loaded by an external clamping system as shown in FIG. 5, an electrical and thermal conducting path is established between the upper electrode 4 and the first conductive structure 14 through each of the semiconductor units 30. In particular, upper surfaces of the chips 20 are electrically and thermally coupled to the upper electrode 4. Lower surfaces of the chips 20 are electrically and thermally coupled to the first conductive structure 14.

In an embodiment, the device 1 is operated by clamping the whole device 1 to a mechanical load greater than a threshold load which depresses the pressure means 40 to such a degree that the lower electrode 5 is pressed flat. Beyond the threshold load, further mechanical loading is applied to the tubular housing element 8 and no further loading is applied to the pressure means 40 or the semiconductor units 30. With reference to FIG. 5, arrows 35 denote the threshold load applied to the semiconductor units 30, and arrows 45 denote the extra load beyond the threshold load that is applied to the tubular housing element 8. In an example, the rated load for the entire device 1 is 50-70 kN, and the threshold load which presses the lower electrode 5 flat may be 40-45 kN, depending upon the number of pressure means 40 within the device 1. This leaves an extra load of about 5-30 kN to be supported by the tubular housing element 8. The individual semiconductor units 30 are generally optimally loaded at the threshold load, and are protected from over-pressurisation by the tubular housing element 8. Given that the device 1 is typically loaded in excess of the threshold load, the semiconductor units 30 are generally not under-pressurised either. In this way, the contact pressures across the semiconductor units 30 stay near or at the optimal level, regardless of the extra loading applied across the device 1. This ensures the optimal performance and the reliability of the device 1.

The use of the pressure means 40 also reduces the contact pressure imbalance across the semiconductor units 30. For example, the pressure means 40 when embodied as disc spring stacks may typically have a maximum stroke of 1 mm or more, whereas the thickness variations of the semiconductor units 30 as well as the displacement of the housing electrodes 4, 5 are typically in the order of tens of microns. Therefore, the pressure means 40 reduce the force/displacement ratio along the vertical Y direction and allow a homogenous distribution of contact pressures across the semiconductor units 30.

The semiconductor units 30, the pillars 10, the recesses 22, the holders 42 and the pressure means 40 are generally aligned along the Y direction. In other words, central axes of the above components are aligned. The aligned arrangement allows each pressure means 40 to most effectively apply pressure to a respective one of the semiconductor units 30.

When the device 1 is not mechanically loaded (as shown in FIG. 4), the plurality of pressure means 40 tend to push the top ends of the holders 22 away from the recesses 22 and also push the lower electrode 5 downwards to make the lower electrode 5 slightly bulge.

FIG. 5 also illustrates a first conductive path P1 which runs from the upper electrode 4, through one of the semiconductor units 30, its corresponding pillar 10, the base plate 12, the tubular conductive structure 16 and the housing lower flange 9, and lead to the lower electrode 5. A second conductive path P2 runs from the upper electrode 4 to the lower electrode 5 through another one of the semiconductor units 30, its corresponding pillars 10, the base plate 12, the tubular conductive structure 16 and the housing lower flange 9. It can be seen that each semiconductor unit has its own conductive path between the upper electrode 4 and the first conductive structure 14, and this conductive path relies upon pressure contact(s) between each individual semiconductor unit 30 and at least one of the upper electrode 4 and the first conductive structure 14.

However, all of the semiconductor units 30 share the same conductive path (which is provided by the tubular conductive structure 16 and the housing lower flange 9) from the first conductive structure 14 to the lower electrode 5. This conductive path routes current around the pressure means 40 and forms a current bypass mechanism, because the pressure means 40 are relatively poor electrical conductors.

Therefore, during normal operation of the device 1, the second conductive structure 18 is designed to carry the electric currents of all of the semiconductor units 30. Therefore, the current density in the second conductive structure 18 is not significantly affected in the event of operation in the short-circuit failure mode, and the second conductive structure 18 is capable of carrying the operating current of the entire device 1 during the short-circuit failure mode.

As described above, the second conductive structure 18 is fixedly connected to the first conductive structure 14 at one end and is fixedly connected to the lower electrode 5 at the other end. Further, components (e.g., the tubular conductive structure 16 and the housing lower flange 9) of the second conductive structure 18 are also fixed connected to one another. Therefore, the current bypass route provided by the second conductive structure 18 from the first conductive structure 14 to the lower electrode 5 is not reliant on any pressure contact. This ensures the current bypass route to have a low electrical resistance, regardless of the external clamping force applied to the device 1. Further, the current bypass route is not vulnerable to fretting wear, and thus remains reliable throughout the product lifetime of the device 1.

The tubular conductive structure 16 is not directly bonded to the lower electrode 5. However, when the device is mechanically loaded, the lower end of the tubular conductive structure 16 may form a pressure contact with the upper surface of the lower electrode 5. Consequently, an amount of electrical current may directly flow from the tubular conductive structure 16 to the lower electrode 5 through the pressure contact. However, the device 1 does not rely upon the pressure contact to route the current from the tubular conductive structure 16 to the lower electrode 5. Even if the pressure contact fails, current can still flow from the tubular conductive structure 16 through the housing lower flange 9 and the interface V3 to the lower electrode 5.

The tubular conductive structure 16 typically has a wall thickness of between about 0.1 mm and about 0.5 mm. The wall thickness is generally determined by consideration of the overall current rating of the device 1, and must be adequate to carry the required current of the device 1. Similarly, the thickness of the base plate 12 may also be determined by consideration of the overall current rating of the device 1.

Preferably, the sidewall of the tubular conductive structure 16 extends continuously between the base plate 12 and the house inner flange 9. This arrangement is beneficial for maximising the conductivity of the tubular conductive structure 16, but may be modified based upon specific requirements of the device 1. For example, slits or holes which extend through the sidewall may be provided so as to allow additional elements to pass through the tubular conductive structure 16.

While FIG. 4 shows that the sidewall of the tubular conductive structure 16 is a straight wall extending along the Y direction, it would be appreciated that at least a part of the sidewall may have a curved contour which deviates from the Y direction. The curved contour accommodates thermal expansion of the tubular conductive structure 16 and is useful to relieve thermo-mechanical strain. The Y direction is parallel to a central axis of the tubular conductive structure 16.

Further, FIGS. 4 and 5 show that the base plate 12, the tubular conductive structure 16 and the housing lower flange 9 are separately provided and then securedly bonded together. It would be appreciated that, alternatively, the base plate 12 and the tubular conductive structure 16 may be integrally formed, and/or the tubular conductive structure 16 and the housing lower flange 9 may be integrally formed.

The device 1 may further comprise a circuit board (not shown in FIG. 4) which is supported by the first surface 13 of the base plate 14. The circuit board may comprise a printed circuit board (PCB) and at least one electrical circuit mounted on the PCB for controlling the operation of the chips 20. Electrical connectors (such as spring loaded pins) are generally used to electrically connect the circuit(s) on the circuit board to electrode pads of the chips 20. For example, if the chips 20 are IGBTs, the circuit board may comprise a driver circuit which generates a gate voltage, and the electrical connectors may connect the gate pad of each chip 20 to an output pad on the circuit board. It would be appreciated that the circuit board and the electrical connectors may be omitted for certain types of chips 20 (e.g., power diodes).

The device 1 may be assembled according to a sequence as follows. For example, the lower electrode 5 may be provided firstly, followed by attaching the plurality of holders 42 to the upper surface of the lower electrode 5. Subsequently, the plurality of pressure means 40 are mounted onto the holders 42. An assembly of the housing lower flange 9, the tubular housing element 8, the tubular conductive structure 16 and the first conductive structure 14 are then bonded to the lower electrode 5 at the interface V3. Subsequently, the semiconductor units 30 are then placed on top of the first conductive structure 14. While it is not shown in FIG. 4, a semiconductor unit locator which is typically made of a high temperature plastic may be used to hold the semiconductor units 30 in place. It follows that the housing upper flange 7, the lid flange 6 and the upper electrode 3 are provided to seal the housing of the device 1. It would be appreciated that the process described above is merely an example of assembling the device 1, and is in no way limiting.

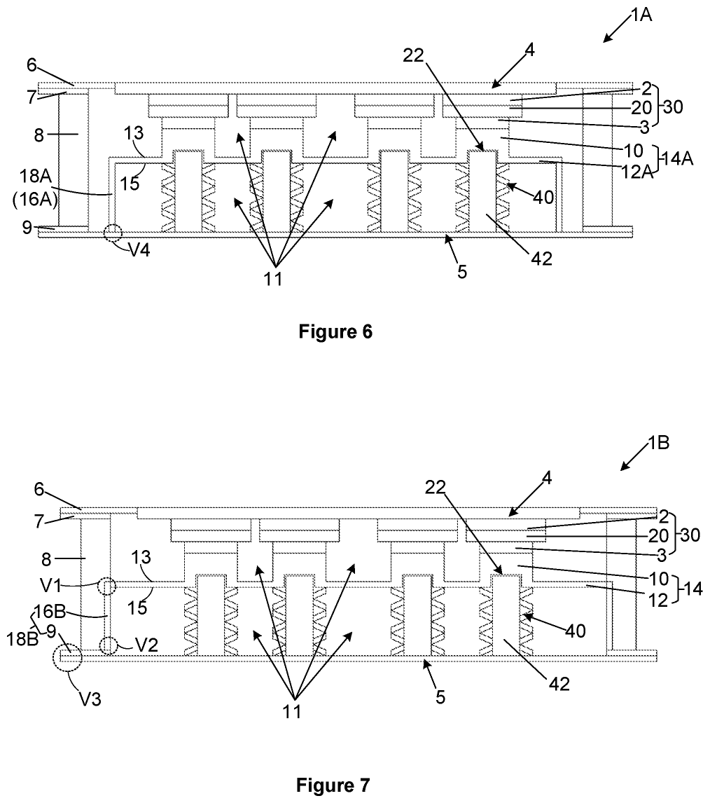

FIG. 6 illustrates a sectional view of a semiconductor device 1A according to a second embodiment of the present disclosure. Elements of the device 1A that are identical to those of the device 1 are identified using the same labels. Elements of the device 1A that correspond to, but are different from those of the device 1 are labelled using the same numerals but with a letter ‘A’ for differentiation. The features and advantages described above with reference to the first embodiment are generally applicable to the second embodiment.

The device 1A differs from the device 1 in that the base plate 12A does not extend to the inner surface of the tubular housing element 8, and the tubular conductive structure 16A is integrally formed with the base plate 12A at its upper end. Further, the lower end of the tubular conductive structure 16A is securedly bonded to the lower electrode 5 at an interface V4. In this way, the tubular conductive structure 16A itself forms a second conductive structure 18A that provides a current flow path from the first conductive structure 14A to the lower electrode 5. The second conductive structure 18A has a first part (e.g., the upper end of the tubular conductive structure 16A) that is fixedly connected to the first conductive structure 14A, and a second part (e.g., the lower end of the tubular conductive structure 16A) that is fixedly connected to the lower electrode 5. A combined structure of the first conductive structure 14A and the tubular conductive structure 16A may be formed by a drawing process. Alternatively, the tubular conductive structure 16A may be separately provided from the first conductive structure 14A, and the upper end of the tubular conductive structure 16A may be secured bonded (e.g., using a brazing, soldering or sintering process) to the base plate 12A of the first conductive structure 14A.

FIG. 7 illustrates a sectional view of a semiconductor device 1B according to a third embodiment of the present disclosure. Elements of the device 1B that are identical to those of the device 1 are identified using the same labels. Elements of the device 1B that correspond to, but are different from those of the device 1 are labelled using the same numerals but with a letter ‘B’ for differentiation. The features and advantages described above with reference to the first embodiment are generally applicable to the third embodiment.

The device 1B differs from the device 1 in that the tubular conductive structure 16B is made integral to the wall of the tubular housing element 8, either as a metallic tube or as a conductive coating applied to the inner surface of the tubular housing element 8 by manual application (for example, using a brush) or by a deposition process. Similar to the device 1 described above, the tubular conductive structure 16B and the housing lower flange 9 of the device 1B may be collectively referred to as a second conductive structure 18B that provides a current flow path from the first conductive structure 14 to the lower electrode 5. The second conductive structure 18B has a first part (e.g., the upper end of the tubular conductive structure 16B) that is securedly bonded to the first conductive structure 14 at an interface V1, and a second part (e.g., the housing lower flange 9) that is securedly bonded to the lower electrode 5 at an interface V3. The tubular conductive structure 16B is securedly bonded to the housing lower flange 9 at an interface V2.

FIGS. 4 to 7 show that each of the devices 1, 1A, and 1B comprises four semiconductor units 30. It would be appreciated that this is purely for conceptual clarity, and that the device may comprise any suitable number (e.g., at least two) of semiconductor units 30. For example, the number of semiconductor units 30 may be chosen based upon the desired overall current rating of the device.

While FIGS. 4 to 7 relate to multi-chip press-pack power semiconductor devices, it would be appreciated that the first conductive structure 14 or 14A and the second conductive structure 18, 18A or 18B may be similarly used within any pressure-contact semiconductor device.

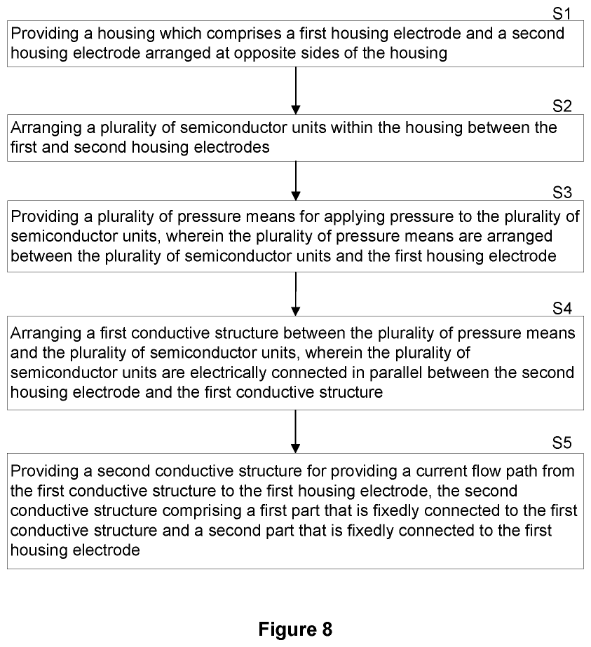

FIG. 8 schematically illustrates processing steps of a method for manufacturing a semiconductor device (e.g., the device 1, 1A or 1B).

At step S1, a housing is provided. The housing comprises a first housing electrode (e.g., the lower electrode 5) and a second housing electrode (e.g., the upper electrode 4) arranged at opposite sides of the housing.

At step S2, a plurality of semiconductor units (e.g., the semiconductor units 30) are arranged within the housing between the first and second housing electrodes. The plurality of semiconductor units may be laterally spaced to one another.

At step S3, a plurality of pressure means (e.g., the pressure means 40) for applying pressure to the plurality of semiconductor units are provided. The plurality of pressure means are arranged between the plurality of semiconductor units and the first housing electrode.

At step S4, a first conductive structure (e.g., the first conductive structure 14 or 14A) is arranged between the plurality of pressure means and the plurality of semiconductor units. The plurality of semiconductor units are electrically connected in parallel between the second housing electrode and the first conductive structure.

At step S5, a second conductive structure (e.g., the second conductive structure 18, 18A, or 18B) for providing a current flow path from the first conductive structure to the first housing electrode is provided. The second conductive structure comprises a first part that is fixedly connected to the first conductive structure and a second part that is fixedly connected to the first housing electrode.

It would be appreciated that the steps may be performed in a temporal order that is different from the order of description. For example, step S1 may comprise two sub-steps, which provide a first part and a second part of the housing, respectively, and steps S2 to S5 may be performed between the two sub-steps. Further, steps S2 to S5 may be performed in any suitable sequence depending upon the particular structure of the semiconductor device.

The terms “having”, “containing”, “including”, “comprising” and the like are open and the terms indicate the presence of stated structures, elements or features but not preclude the presence of additional elements or features. The articles “a”, “an” and “the” are intended to include the plural as well as the singular, unless the context clearly indicates otherwise.

The skilled person will understand that in the preceding description and appended claims, positional terms such as ‘upper’, ‘lower’, ‘top’, ‘bottom’, ‘lateral’, ‘vertical’ etc. are made with reference to conceptual illustrations of a semiconductor device, such as those showing standard layout plan views and those shown in the appended drawings. These terms are used for ease of reference but are not intended to be of limiting nature. These terms are therefore to be understood as referring to a semiconductor device when in an orientation as shown in the accompanying drawings.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in the disclosure, whether alone or in any appropriate combination with any other feature disclosed or illustrated herein.

1. A semiconductor device, comprising:
a housing comprising a first housing electrode and a second housing electrode which are arranged at opposite sides of the housing;
a plurality of semiconductor units arranged within the housing between the first and second housing electrodes;
a plurality of pressure applicators configure to apply to the plurality of semiconductor units, wherein the plurality of pressure applicators are arranged between the plurality of semiconductor units and the first housing electrode;
a first conductive structure arranged between the plurality of pressure applicators and the plurality of semiconductor units, wherein the plurality of semiconductor units are electrically connected in parallel between the second housing electrode and the first conductive structure; and
a second conductive structure configured to provide a current flow path from the first conductive structure to the first housing electrode, the second conductive structure comprising a first part that is fixedly connected to the first conductive structure and a second part that is fixedly connected to the first housing electrode.

2. A semiconductor device according to claim 1, wherein the plurality of semiconductor units are electrically and thermally coupled to one another via the first conductive structure.

3. A semiconductor device according to claim 1, wherein the first conductive structure is a unitary one-piece structure.

4. A semiconductor device according to claim 1, wherein the first conductive structure comprises a base plate and a plurality of pillars, and wherein the base plate comprises a first surface facing the plurality of semiconductor units and a second surface opposite to the first surface, and the plurality of pillars extend from the first surface of the base plate, and are electrically coupled to the plurality of semiconductor units, respectively.

5. A semiconductor device according to claim 1, wherein at least one of the plurality of pressure applicators are elastic.

6. A semiconductor device according to claim 1, wherein the plurality of pressure applicators are configured to apply pressure to the plurality of semiconductor units when the plurality of pressure applicators are compressed between the first housing electrode and the first conductive structure.

7. A semiconductor device according to claim 1, wherein at least one of the plurality of pressure applicators comprises a spring.

8. A semiconductor device according to claim 1, further comprising a plurality of holders for keeping the plurality of pressure applicators in place within the housing.

9. A semiconductor device according to claim 8, wherein the first conductive structure comprises a plurality of recesses for engaging with the plurality of holders, respectively.

10. A semiconductor device according to claim 9, wherein the plurality of pressure applicators are configured to apply pressure to the plurality of semiconductor units when the plurality of recesses engage with the plurality of holders, respectively.

11. A semiconductor device according to claim 1, wherein the pressure applicators is configured to apply maximum pressure to the plurality of semiconductor units when the first housing electrode is pressed flat by an external clamping system.

12. A semiconductor device according to claim 11, wherein the housing further comprises a tubular housing element arranged between the first and second housing electrodes and surrounding the plurality of semiconductor units, wherein the tubular housing element is configured to electrically isolate the first and second housing electrodes from one another; and wherein the tubular housing element is configured such that, once the first housing electrode is pressed flat by the external clamping system, further mechanical loading provided by the external clamping system is applied to the tubular housing element.

13. (canceled)

14. A semiconductor device according to claim 1, wherein the second conductive structure comprises a tubular conductive structure arranged within the housing.

15. A semiconductor device according to claim 14, wherein the tubular conductive structure comprises a wall, and a thickness of the wall is between 0.1 mm and 0.5 mm.

16. A semiconductor device according to claim 14, wherein at least a part of a wall of the tubular conductive structure has a curved contour along a direction parallel to a central axis of the tubular conductive structure.

17. A semiconductor device according to claim 14, wherein the tubular conductive structure is formed integrally with the first conductive structure.

18. (canceled)

19. A semiconductor device according to claim 1, wherein the housing further comprises a tubular housing element arranged between the first and second housing electrodes and surrounding the plurality of semiconductor units, wherein the tubular housing element is configured to electrically isolate the first and second housing electrodes from one another; and wherein the housing further comprises a first flange connecting the first housing electrode to the tubular housing element, and a second flange connecting the second housing electrode to the tubular housing element.

20. A semiconductor device according to claim 19, wherein the second conductive structure comprises a tubular conductive structure arranged within the housing; and wherein the second conductive structure further comprises the first flange, and the first flange is fixedly connected to the tubular conductive structure, and wherein the tubular conductive structure comprises the first part, and the first flange comprises the second part.

21. A semiconductor device according to claim 1, wherein: the housing further comprises a tubular housing element arranged between the first and second housing electrodes and surrounding the plurality of semiconductor units, wherein the tubular housing element is configured to electrically isolate the first and second housing electrodes from one another; the second conductive structure comprises a tubular conductive structure arranged within the housing; and the tubular conductive structure is attached to an inner surface of the tubular housing element.

22. (canceled)

23. (canceled)

24. A method of manufacturing a semiconductor device, comprising:
providing a housing, wherein the housing comprises a first housing electrode and a second housing electrode which are arranged at opposite sides of the housing,
arranging a plurality of semiconductor units within the housing between the first and second housing electrodes;
providing a plurality of pressure applicators configure to apply to the plurality of semiconductor units, wherein the plurality of pressure applicators are arranged between the plurality of semiconductor units and the first housing electrode;
arranging a first conductive structure between the plurality of pressure applicators and the plurality of semiconductor units, wherein the plurality of semiconductor units are electrically connected in parallel between the second housing electrode and the first conductive structure; and
providing a second conductive structure for providing a current flow path from the first conductive structure to the first housing electrode, the second conductive structure comprising a first part that is fixedly connected to the first conductive structure and a second part that is fixedly connected to the first housing electrode.
